(19) United States
(12) Patent Application Publication
(10) Pub. No.: US 2004/0209172 A1
(43) Pub. Date: Oct. 21, 2004

(54) Defect correction method for a photomask

(76) Inventors: Osamu Takaoka, Chiba-shi (JP); Kazuo Aita, Chiba-shi (JP); Fumio Aramaki, Chiba-shi (JP)

Correspondence Address: ADAMS & WILKS, ATTORNEYS AND COUNSELORS AT LAW, 50 BROADWAY, 31st FLOOR, NEW YORK, NY, 10004, US

(21) Appl. No.: 10/809,593

(22) Filed: Mar. 25, 2004

(30) Foreign Application Priority Data
Apr. 3, 2003 (JP) 2003-099925

(51) Int. Cl. G03F 9/00; G06F 17/50; G01L 21/30; C23F 3/00; C23F 1/00; B44C 1/22; G01R 31/00

(52) U.S. Cl. 430/5; 716/19; 216/59; 216/60; 216/74

(57) ABSTRACT

In order to enable the correction of clear defects, opaque defects, and Levenson mask glass projection defects using one species of gas, by changing gas pressure and probe current and scanning conditions of the ion beam 2, the diacetone acrylamide is capable of forming a light-blocking film 17 correcting clear defects on a glass substrate 16 and a chrome pattern 15, is capable of removing chrome and glass at a high etching rate, and is capable of eliminating opaque defect regions 18 and eliminating glass projection defect regions 19. It is therefore possible to carry out correction by changing gas supplying conditions and ion beam irradiation conditions according to whether the correction is clear defect correction, opaque defect correction, or Levenson mask glass projection defect correction.

### BACKGROUND OF THE INVENTION

1. Field Of The Invention

The present invention relates to a defect correction method for a photomask or reticle.

2. Description Of Related Art

As fine detailing of Si semiconductor integrated circuits has advanced at a remarkable rate, so too has the fineness of pattern dimensions on a photomask or reticle employed in transfer. Reduced size projection exposure devices are therefore compatible for use with numerical apertures and short wavelength light in line with these demands. When a defect exists on the photomask or reticle, the defect is transferred to a wafer and causes yield to be reduced. Photomasks and reticles are then checked for the presence or absence of defects and the location of such defects using a defect-checking device prior to transferring the mask pattern to a wafer. When defects exist, defect correction processing is carried out using a defect correction device before transfer to a wafer. As a result of trends in this technology, there are also demands for photomask or reticle defect correction compatible with small defects. Focused ion beam devices employing liquid metal Ga ion sources are in the main part replacing defect correction devices employing lasers due to their fine processing dimensions. With defect correction devices employing ion beams, at the time of clear defect correction, thin films (FIB=−CVD) are only formed at locations when an ion beam has been focused to absorb source material gas in the case of opaque defects, effects where etching is possible while maintaining a high transmission factor in the presence of an assist gas is utilized to achieve highly accurate high-quality processing.

Different materials are used for the light-blocking film material used in clear defect correction and for the assist gas used in opaque defect correction. A carbon-containing alloy such as styrene, pyrene, phenanthrene, or naphthalene is used as the light-blocking film material for clear defect correction use. Halide gases such as iodine, bromine, or fluorinated xenon are used as assist gases for opaque defect correction use. The light-blocking film material for clear defect correction use is not only formed as a film on glass, but is also formed as a film on patterns due to half-tone defect correction requirements so that resistance to washing is also achieved. Assist gases for opaque defect correction achieve a high etch rate while maintaining a high transmission factor and keeping the influence of drift small.

With the current acceleration of fine detail, phase shift masks that are a type of superresolution technology have also come to be used in order to increase resolution and increase focal point depth by using reduced size projection exposure devices as is. Levenson half-tone phase shift photomasks exist as phase-shift photomasks, with it being well-known that improvements in resolution are larger for Levenson photomasks. However, it is difficult to optimize the phase shift arrangement with Levenson photomasks. As a result of this, there is the disadvantage that improvements in resolution results are few. This is, however, still widely used because this makes the introduction of a light-blocking film with a half-tone film easier with there being few changes to make from binary mask technology. However, even with having to overcome the problems with the aforementioned design techniques in order to further improve resolution-, examples of mask manufacturing employing Levenson photomasks where the improvements in resolution are substantial are increasing. Types of Levenson phase shift masks that exist include types where a transparent phase-shifting film is positioned, and types where a glass or quartz substrate is excavated to a depth capable of inverting phase. The types where a glass or silica substrate is excavated are currently implemented in the main. These are Levenson-type phase masks where a glass or quartz substrate is excavated to a depth capable of inverting phase only at portions of a binary mask requiring finely detailed patterning. Methods where a glass substrate irradiated with an ion beam in a fluorinated xenon or iodine gas atmosphere so as to suppress Ga injection is etched while maintaining a high transmission factor are well-known as methods for eroding glass with a focused ion beam device.

A minimum of at least two gas providing systems are required for clear defect correction use and opaque defect correction use, which means that, as a further gas system is also prepared for glass projection defect correction of the Levenson mask, a total of at least three gas providing systems are required, which makes the device configuration complex. There are therefore space restrictions with regards to providing two or three systems with gas guns for providing gas to the vicinity of the ion beam irradiation position, and in cases where a plurality of types of gas are provided to the vicinity of the ion beam irradiation position by sharing the same gas gun, purging accompanying switching over of the gas is necessary.

The present invention is for resolving the aforementioned problems and provides that advantages of a device configuration that is simple compared to that of the related art and that achieves savings with regards to space required for gas supplying systems. Purges in order to change the gas over are also not required, and by carrying out clear defect and opaque defect correction using one species of gas, all of the requirements demanded by Levenson mask glass projection defect correction can be satisfied.

### SUMMARY OF THE INVENTION

In the photomask defect method of the invention of this application, diacetone acrylamide (standard nomenclature: N-(1,1 dimethyl-3-oxobutyl) acrylic amide) is used as a supplied gas, and ion beam irradiation conditions or a gas pressure of the diacetone acrylamide are switched over. Diacetone acrylamide is capable of forming a light-blocking film on a glass substrate or on a chrome pattern by changing the gas pressure and ion beam irradiation conditions. It is also capable of removing chrome or glass at a high etch rate. It is therefore possible to carry out various corrections by changing gas supplying conditions or ion beam irradiation conditions according to whether the correction is clear defect correction, opaque defect correction, or Levenson mask glass projection defect correction.

Since only one type of gas is used for defect corrections, it is possible to correct clear defects, opaque defects, and Levenson mask glass projection defects with a device configuration that is simple compared to the device of the related art. Gas purge accompanying changing over of the gas type is no longer necessary, and problems relating to making space for locating gas guns no longer exist.

### BRIEF DESCRIPTION OF THE DRAWINGS

FIG. 1 is an outline cross-sectional view preferably expressing the characteristics of the present invention, where FIG. 1(a) is the case of correcting a clear defect, FIG. 1(b) is the case of correcting an opaque defect, and FIG. 1(c) is the case of correcting Levenson mask glass projection defects.

FIG. 2 is an outline view of a photomask defect correction device employing an ion beam for illustrating this embodiment.

### DETAILED DESCRIPTION OF THE PREFERRED EMBODIMENT

The following is a description of an embodiment of the present invention.

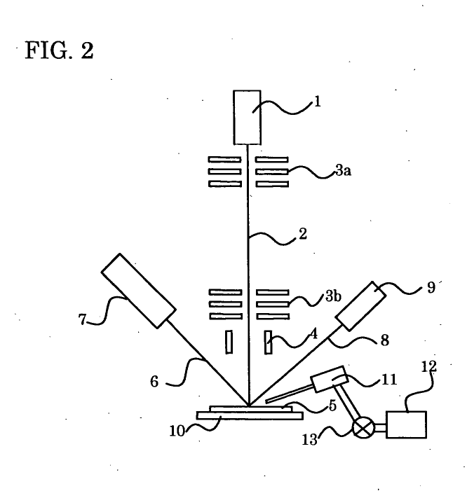

The photomask 5 containing defects is introduced into the vacuum chamber of the ion beam defect correction device shown in FIG. 2, and an XY stage 10 is moved so that a defect position detected by the defect detection device is irradiated with an ion beam. First, an ion beam 2 accelerated to from 20 to 30 kV emitted from an ion source 1 is focused by a condenser lens 3a and an object lens 3b, and is then made to scan the photomask 5 using a deflector 4. Secondary electrons or secondary ions 6 generated at this time are simultaneously taken in by a secondary electron detector or a secondary ion detector 7, and regions requiring defect correction (clear defects, opaque defects, or Levenson mask glass projection defects) are recognized. At the time of acquiring a secondary electron image or a secondary ion image, irradiation with an electron beam 8 focused by acceleration through a few hundred volts using a charge-neutralizing electron gun 9 takes place, and a state where charge is neutralized is observed. This is in order to prevent a secondary electron image or secondary ion image from no longer being visible as a result of the accumulation of positive ions of the ion beam due to the photomask 5 being laminated from a conductive light-blocking pattern on a glass substrate constituting an insulating body.

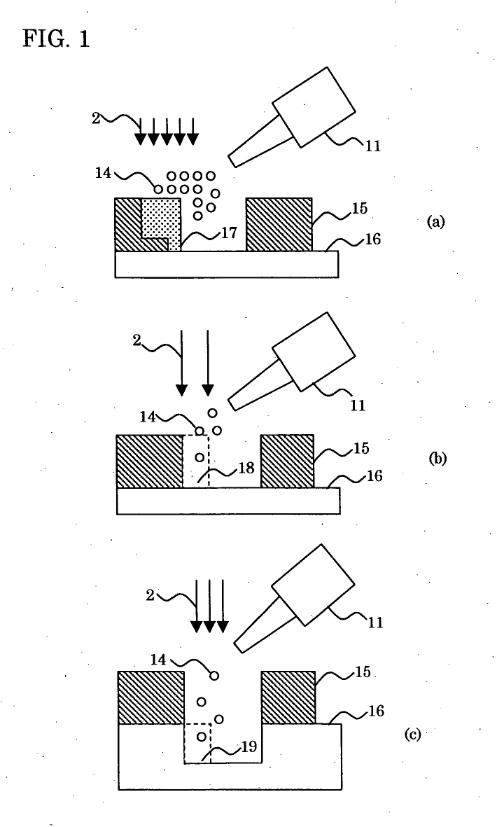

Diacetone acrylamide gas 14 is supplied as light-blocking film material from the gas gun 11 arranged in the vicinity of the position of irradiation of the ion beam as shown in FIG. 1(a) for regions confirmed as being clear defects. The diacetone acrylamide gas 14 is controlled to be at a favorable gas pressure for light-blocking film-forming using temperature control. The ion beam then selectively scans only defect regions at a probe current and at scanning conditions optimized for the forming of a light-blocking film. The diacetone acrylamide is then broken down so as to form a light-blocking film 17 and correct the clear defect. In the case of a normal clear defect, a light-blocking film is formed on the glass substrate 16, and in the case of a half-tone defect, a light-blocking film is formed on chrome 15.

Diacetone acrylamide gas 14 is also supplied from the gas gun 11 arranged in the vicinity of the irradiation position of the ion beam shown in FIG. 1(b) for regions identified as being opaque defects. However, in this case, diacetone acrylamide gas 14 is provided in such a manner that a high transmission factor is maintained using temperature control and with gas pressure (a gas pressure enabling accelerated etching) being controlled in such a manner that erosion takes place at a high etching rate. Further, an ion beam only selectively scans defect regions while maintaining a high transmission factor and with probe current and scanning conditions optimized to as to give erosion at a high etching rate, chrome of the opaque defect region 18 is removed, and the opaque defect is corrected. When diacetone acrylamide is used as an etching gas, it is not possible to obtain a selection ratio between chrome and glass, end point detection is carried out by monitoring a secondary ion signal during processing, and high-quality opaque defect correction is carried out without the base glass substrate being subjected to damage.

Diacetone acrylamide gas 14 is also supplied from the gas gun 11 arranged in the vicinity of the irradiation position of the ion beam shown in FIG. 1(c) for Levenson mask glass projection defects. In this case also, as in the case of opaque defect correction, diacetone acrylamide gas 14 is provided in such a manner that a high transmission factor is maintained using temperature control and with gas pressure being controlled in such a manner that removal takes place at a high etching rate. Further, an ion beam only selectively scans defect regions while maintaining a high transmission factor and with probe current and scanning conditions optimized so as to give erosion at a high etching rate, glass of the glass projection defect region 19 is removed, and the glass defect is corrected. The irradiation amount of the ion beam 2 is controlled in such a manner that the defect correction region does not become deeper than the eroded glass surface.

As described above, according to this invention, since diacetone acrylamide enables to correct clear defects, opaque defects, and Levenson mask glass projection defects, a device configuration becomes simple compared to the device of the related art. Gas purge accompanying changing over of the gas type is no longer necessary, and a space for locating gas guns is reduced.

What is claimed is:

1. A photomask defect correction method for a photomask defect correction device employing an ion beam equipped with a function for introducing diacetone acrylamide to an ion beam irradiation position and the vicinity of the ion beam irradiation position, capable of carrying out both clear defect correction and opaque defect correction using a single gas species by changing irradiation quantity or irradiation density of the ion beam, scanning conditions, and gas pressure conditions during processing.

2. The photomask defect correction method as disclosed in claim 1, wherein the photomask defects are projection defects of a glass trench-type Levenson mask.

3. A photomask defect correction method employing a photomask defect correction device employing an ion beam equipped with a function for introducing diacetone acrylamide to an ion beam irradiation position and the vicinity of the ion beam irradiation position, wherein clear defects are corrected using diacetone acrylamide as a source gas for a light-blocking film.

4. A photomask defect correction method employing a photomask defect correction device employing an ion beam equipped with a function for introducing diacetone acrylamide to an ion beam irradiation position and the vicinity of the ion beam irradiation position, wherein opaque defects are corrected using diacetone acrylamide as an etching gas.

5. A photomask defect correction method using a photomask defect correction device employing an ion beam equipped with a function for introducing diacetone acrylamide to an ion beam irradiation position and to the vicinity of the ion beam irradiation position, wherein projection defects of a glass trench-type Levenson mask are corrected using diacetone acrylamide as an etching gas.
